(19) United States
(12) Patent Application Publication
(10) Pub. No.: US 2023/0400507 A1
(43) Pub. Date: Dec. 14, 2023

(54) INFORMATION PROCESSING APPARATUS AND DEGRADATION ESTIMATION METHOD

(71) Applicant: Fujitsu Limited, Kawasaki-shi (JP)

(72) Inventor: Keigo TAKEDA, Shinagawa (JP)

(73) Assignee: Fujitsu Limited, Kawasaki-shi (JP)

(21) Appl. No.: 18/179,689

(22) Filed: Mar. 7, 2023

(30) Foreign Application Priority Data
Jun. 13, 2022 (JP) 2022-094871

(51) Int. Cl. G01R 31/28

(52) U.S. Cl. CPC G01R 31/2882; G01R 31/287

(57) ABSTRACT

A sensor acquires an operating condition of a target circuit. When an operating condition changes, a control circuit corrects an operating time of the target circuit based on a changed operating condition to obtain a corrected operating time, and calculates performance degradation information of the target circuit by using the changed operating condition and the corrected operating time.

### CROSS-REFERENCE TO RELATED APPLICATION

This application is based upon and claims the benefit of priority of the prior Japanese Patent Application No. 2022-094871, filed on Jun. 13, 2022, the entire contents of which are incorporated herein by reference.

### FIELD

The embodiments discussed herein relate to a degradation estimation technique.

### BACKGROUND

In recent years, with an increase in scale of an integrated circuit to be used in an information processing apparatus (computer), an increase in operating speed, and miniaturization of a process, malfunction due to a delay failure caused by degradation of the integrated circuit over time has become a problem. In particular, in the case of an information processing apparatus requiring high reliability, from the viewpoint of safety design of an integrated circuit itself, it is desirable to detect a change in circuit characteristics over time before a failure due to degradation over time becomes apparent. As a performance degradation amount indicating the performance degradation of the integrated circuit, for example, the amount of increase in the propagation delay time of a signal is used.

An accelerated processing unit (APU) equipped with adaptive voltage-frequency scaling (AVFS) using a replica path is known in connection with a technique for detecting the amount of increase in the propagation delay time (see, for example, Non-Patent Document 1). A degradation detection circuit that detects degradation of a large-scale Integration (LSI) in a semiconductor device before the degradation becomes fatal is also known (see, for example, Patent Document 1). A method of estimating the lifetime of a semiconductor device is also known (see, for example, Patent Document 2).
Patent Document 1: Japanese Laid-open Patent Publication No. 2013-168574
Patent Document 2: Japanese Laid-open Patent Publication No. 2003-282590
Non-Patent Document 1: K. Wilcox et al., “4.8 A 28 nm x86 APU Optimized for Power and Area Efficiency”, 2015 IEEE International Solid-State Circuits Conference—(ISSCC) Digest of Technical Papers, 3 pages, 2015.

### SUMMARY

According to an aspect of the embodiments, an information processing apparatus includes a sensor and a control circuit. The sensor acquires an operating condition of a target circuit. When the operating condition changes, the control circuit corrects an operating time of the target circuit based on a changed operating condition to obtain a corrected operating time, and calculates performance degradation information of the target circuit by using the changed operating condition and the corrected operating time.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 is a graph illustrating a performance degradation amount estimated using a fitting equation;

FIG. 2 is a functional configuration diagram of an information processing apparatus according to an embodiment;

FIG. 3 is a flowchart of first degradation estimation processing;

FIG. 4 is a functional configuration diagram illustrating a specific example of the information processing apparatus;

FIG. 5 illustrates a circuit model;

FIG. 6 is a flowchart of second degradation estimation processing;

FIG. 7 is a flowchart of calculation equation generation processing;

FIG. 8 is a flowchart of simulation processing;

FIG. 9 is a flowchart of circuit simulation;

FIG. 10 is a flowchart of performance degradation amount calculation processing;

FIG. 11 illustrates a performance degradation amount calculated by the performance degradation amount calculation processing;

FIG. 12 is a flowchart of detection processing;

FIG. 13 is a flowchart of correction amount setting processing;

FIG. 14 illustrates variables stored in a FIFO manner;

FIG. 15A illustrates constants indicated by calculation equation information generated in the second degradation estimation processing;

FIG. 15B illustrates operating conditions in the second degradation estimating processing;

FIG. 15C illustrates performance degradation amounts estimated by the second degradation estimation processing;

FIG. 16 is a graph illustrating a performance degradation amount estimated by the second degradation estimation processing;

FIG. 17 is a first hardware configuration diagram of the information processing apparatus;

FIG. 18 is a hardware configuration diagram of an integrated circuit;

FIG. 19 is a hardware configuration diagram of a CPU die;

FIG. 20 is a flowchart of control processing;

FIG. 21 is a flowchart of operating mode selection processing;

FIG. 22 is a second hardware configuration diagram of the information processing apparatus;

FIG. 23 is a third hardware configuration diagram of the information processing apparatus; and

FIG. 24 is a fourth hardware configuration diagram of the information processing apparatus.

### DESCRIPTION OF EMBODIMENTS

Hereinafter, embodiments will be described in detail with reference to the drawings.

In the APU described in Non-Patent Document 1, the degradation of the APU is detected by detecting a temporal change in propagation delay time in a replica circuit of a critical path. The critical path is a data path having the longest propagation delay time. Since a data path that can be the critical path changes according to a voltage or temperature of the APU, data paths having various circuit configurations are implemented.

For each data path, a pulse signal output from the replica circuit is compared with a reference signal obtained by delaying the pulse signal, and when the two signals do not match, an error signal called Near Miss is output at a high level.

However, when a replica circuit is mounted on an integrated circuit such as an APU, a control circuit, a measurement circuit, and the like of the replica circuit are also mounted, and thus an effective circuit area of the integrated circuit decreases.

On the other hand, in a method of estimating a performance degradation amount of an integrated circuit using a fitting equation in which the voltage, the temperature, and the operating time of the integrated circuit are variables, since it is not necessary to implement a replica circuit, the problem of a decrease in an effective circuit area of the integrated circuit does not occur.

In this estimation method, the fitting equation is generated from a result of circuit simulation by Simulation Program with Integrated Circuit Emphasis (SPICE) using a circuit model based on degradation of a transistor over time.

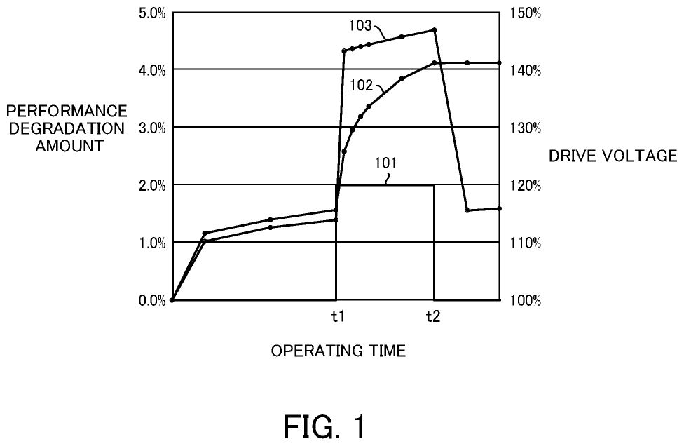

FIG. 1 is a graph illustrating an example of a performance degradation amount estimated using the fitting equation. The performance degradation amount represents the amount of increase in the propagation delay time of a signal. The horizontal axis represents the operating time. The operating time is an elapsed time from the start of operation of the integrated circuit.

A polygonal line 101 indicates a temporal change in the drive voltage of the integrated circuit. The drive voltage is normalized with the rated voltage as 100%. The drive voltage is 100% during the operating time from 0 to t1. The drive voltage increases to 120% when the operating time is t1. The drive voltage is 120% during the operating time from t1 to t2. The drive voltage decreases to 100% when the operating time is t2.

A polygonal line 102 indicates a temporal change in the actual performance degradation amount of the integrated circuit. When the operating time is 0, the performance degradation amount is 0%. The performance degradation amount is less than 2% during the operating time from 0 to t1. The performance degradation amount increases when the operating time is t1. The performance degradation amount continuously increases during the operating time from t1 to t2, and the increase stops when the operating time is t2.

A polygonal line 103 indicates a temporal change in the performance degradation amount estimated using the fitting equation. The estimated performance degradation amount indicates a value close to the polygonal line 102 during the operating time from 0 to t1, but when the operating time is t1, the estimated performance degradation amount increases more rapidly than the polygonal line 102. The estimated performance degradation amount continuously increases during the operating time from t1 to t2. The estimated performance degradation amount rapidly decreases when the operating time is t2.

As described above, when the drive voltage changes during the operation of the integrated circuit, the performance degradation amount estimated using the fitting equation deviates from the actual performance degradation amount regardless of the time period from t1 to t2 in which the drive voltage increases. Similar deviation occurs when the temperature changes during the operation of the integrated circuit. Therefore, this estimation method is effective only under the condition that the drive voltage and the temperature do not change until the end of life of the integrated circuit.

However, a recent integrated circuit has a function of adjusting a voltage and a clock frequency according to a load or a junction temperature, such as AVFS or Dynamic Voltage and Frequency Scaling (DVFS). In this case, since the voltage or the temperature changes during the operation of the integrated circuit, it is difficult to accurately estimate the performance degradation amount using the fitting equation.

As described above, when the performance degradation amount of the integrated circuit is estimated using the fitting equation in which the voltage, the temperature, and the operating time of the integrated circuit are variables, if operating conditions such as the voltage and the temperature change during the operation of the integrated circuit, the accuracy of the estimated performance degradation amount may decrease.

Note that such a problem occurs not only in an integrated circuit but also in various circuits whose performance is degraded with changes in operating conditions.

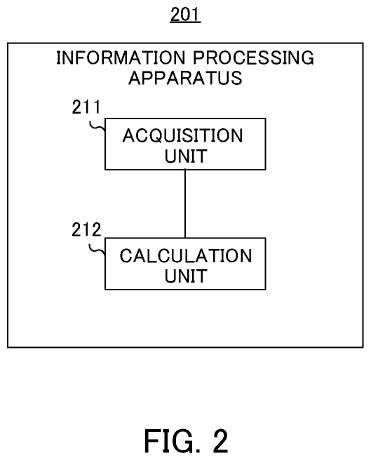

FIG. 2 is a functional configuration diagram of an information processing apparatus according to an embodiment. The information processing apparatus 201 illustrated in FIG. 2 includes an acquisition unit 211 and a calculation unit 212.

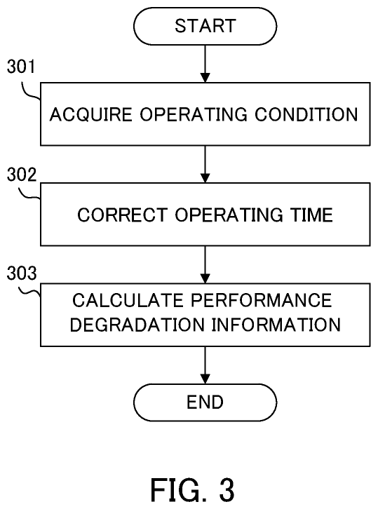

FIG. 3 is a flowchart illustrating an example of first degradation estimation processing performed by the information processing apparatus 201 illustrated in FIG. 2. First, the acquisition unit 211 acquires an operating condition of a target circuit (step 301). Next, when the operating condition changes, the calculation unit 212 corrects the operating time of the target circuit based on a changed operating condition to obtain a corrected operating time (step 302), and calculates performance degradation information of the target circuit by using the changed operating condition and the corrected operating time (step 303).

According to the information processing apparatus 201 illustrated in FIG. 2, it is possible to improve the accuracy of estimating information indicating performance degradation of a circuit.

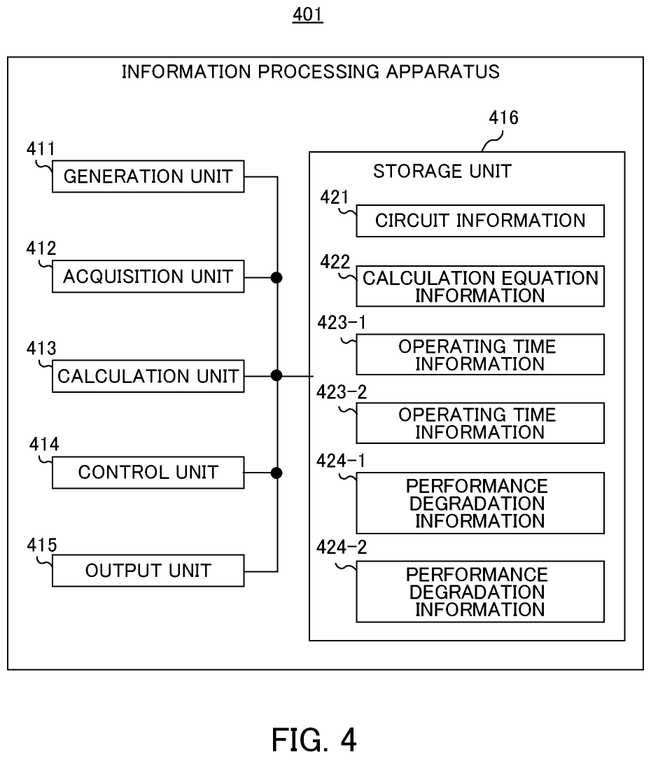

FIG. 4 illustrates a specific example of the information processing apparatus 201 illustrated in FIG. 2. An information processing apparatus 401 illustrated in FIG. 4 includes a generation unit 411, an acquisition unit 412, a calculation unit 413, a control unit 414, an output unit 415, and a storage unit 416. The acquisition unit 412 and the calculation unit 413 correspond to the acquisition unit 211 and the calculation unit 212 illustrated in FIG. 2, respectively.

The information processing apparatus 401 estimates, as a performance degradation amount, the amount of increase in the propagation delay time of a signal in an integrated circuit TC to be monitored. The integrated circuit TC corresponds to a target circuit. The integrated circuit TC is, for example, an LSI circuit equipped with an arithmetic processing device such as a central processing unit (CPU), a graphics processing unit (GPU), or an APU included in the information processing apparatus 401. The arithmetic processing device may also be referred to as a processor.

The storage unit 416 stores circuit information 421. The circuit information 421 includes information indicating a net list of a circuit model representing the integrated circuit TC. As the circuit model, for example, a circuit in which a plurality of gate elements is connected is used. The circuit model may represent a critical path included in the integrated circuit TC.

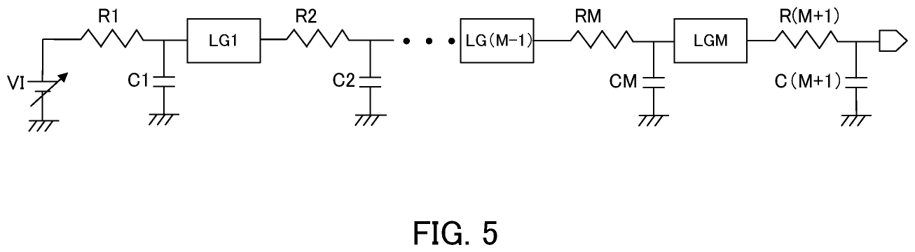

FIG. 5 illustrates an example of the circuit model. The circuit model illustrated in FIG. 5 includes a step signal source VI, wiring resistors R1 to R(M+1), parasitic capacitances C1 to C(M+1), gate elements LG1 to LGM, and an output terminal 501. M is an integer of 2 or more. Each parasitic capacitance Ci (i=1 to M+1) represents a parasitic capacitance between a wiring line and the ground. In FIG. 5, a power supply for driving each gate element LGi (i=1 to M) is omitted.

The step signal source VI inputs a step signal to the gate element LG1. Each gate element LGi is any type of gate element. The gate elements LG1 to LGM may be different types of gate elements.

In a case where a multi-input gate element is used as a gate element LGi, an empty pin is connected to the ground or a power supply which supplies a power supply voltage VDD that is a drive voltage. As a result, the input step signal propagates through the multi-input gate element. The gate elements LG1 and LGM are desirably used as buffers for reducing the effect of infinite output impedance of an ideal power supply or infinite impedance of the load.

The acquisition unit 412 includes a voltage sensor and a temperature sensor. The voltage sensor acquires a voltage of the integrated circuit TC, and the temperature sensor acquires a temperature of the integrated circuit TC. For example, the drive voltage is used as the voltage of the integrated circuit TC. The drive voltage represents the power supply voltage applied to the integrated circuit TC. As the temperature of the integrated circuit TC, for example, an operating environment temperature is used. The voltage and the temperature correspond to an operating condition of the integrated circuit TC.

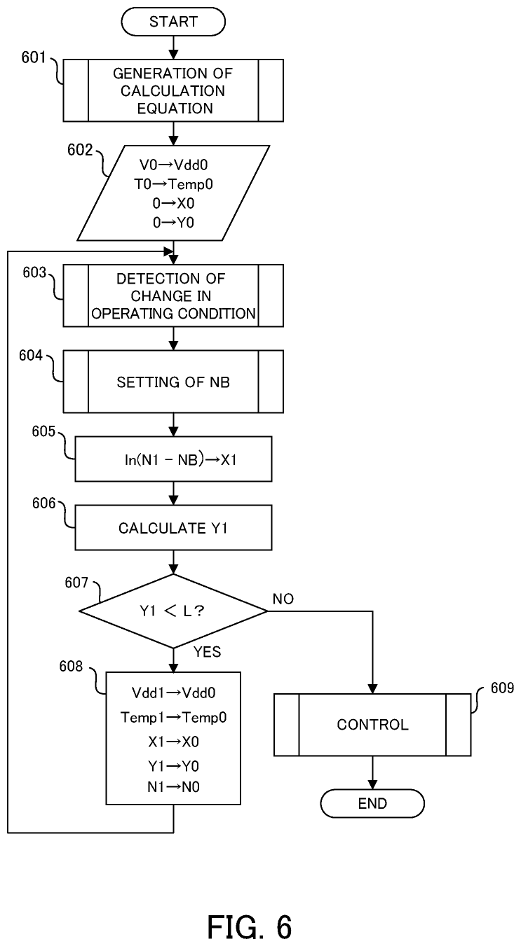

FIG. 6 is a flowchart illustrating an example of second degradation estimation processing performed by the information processing apparatus 401 illustrated in FIG. 4.

Vdd0 and Vdd1 are variables representing the voltage of the integrated circuit TC, and Temp0 and Temp1 are variables representing the temperature of the integrated circuit TC. N0 and N1 are variables representing the operating time of the integrated circuit TC, and X0 and X1 are variables representing the natural logarithm of the operating time of the integrated circuit TC. Y0 and Y1 are variables representing the natural logarithm of the performance degradation amount of the integrated circuit TC. Any unit (a.u.) can be used as the unit of the operating time.

First, the generation unit 411 performs circuit simulation using the circuit information 421 to generate a calculation equation for estimating the performance degradation amount Δdp of the integrated circuit TC from the voltage Vdd, the temperature Temp, and the operating time N of the integrated circuit TC (step 601). Then, the generation unit 411 stores calculation equation information 422 indicating the generated calculation equation to the storage unit 416.

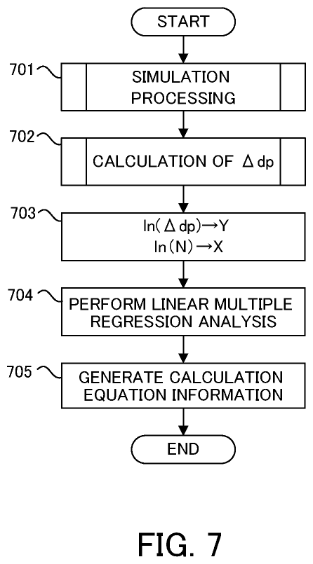

FIG. 7 is a flowchart illustrating an example of the calculation equation generation processing in step 601 illustrated in FIG. 6. First, the generation unit 411 performs simulation processing using the circuit information 421 to generate a simulation result for each of a plurality of combinations of the voltage, the temperature, and the operating time (step 701).

Next, the generation unit 411 calculates Δdp from the result of the circuit simulation for each combination of the voltage, the temperature, and the operating time (step 702), and sets the following calculation equation.

Y=d×X+a×Vdd+b×Temp+c (1)

X is an explanatory variable representing the natural logarithm ln(N) of the operating time N, and Y is an objective variable representing the natural logarithm ln(Δdp) of Δdp. a, b, c, and d are unknown constants. Equation (1) may also be referred to as a fitting equation.

Next, the generation unit 411 sets the natural logarithm ln(Δdp) of each Δdp calculated in step 702 to Y, and sets the natural logarithm ln(N) of N corresponding to Δdp to X (step 703). Then, the generation unit 411 determines the values of a, b, c, and d by performing linear multiple regression analysis (step 704), generates calculation equation information 422 including the determined values of a, b, c, and d, and stores the generated calculation equation information 422 to the storage unit 416 (step 705).

By storing the values of a, b, c, and d in the storage unit 416, Δdp at arbitrary operating time, voltage, and temperature can be estimated.

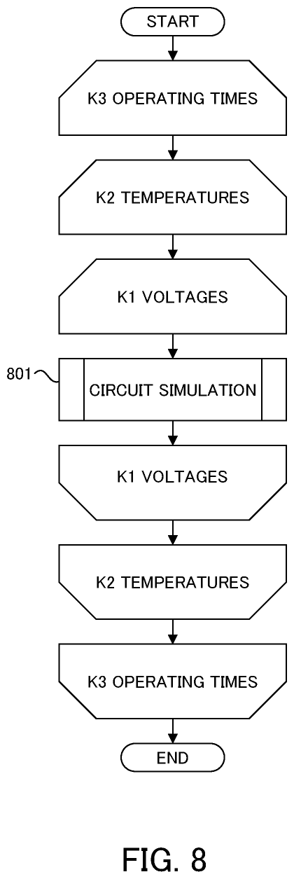

FIG. 8 is a flowchart illustrating an example of the simulation processing in step 701 illustrated in FIG. 7. The generation unit 411 repeats circuit simulation in step 801 using a combination of each of K1 voltages in a predetermined voltage range, each of K2 temperatures in a predetermined temperature range, and each of K3 operating times in a predetermined time range. K1, K2, and K3 are integers of 2 or more. In this case, the number of iterations of the circuit simulation is K1×K2×K3.

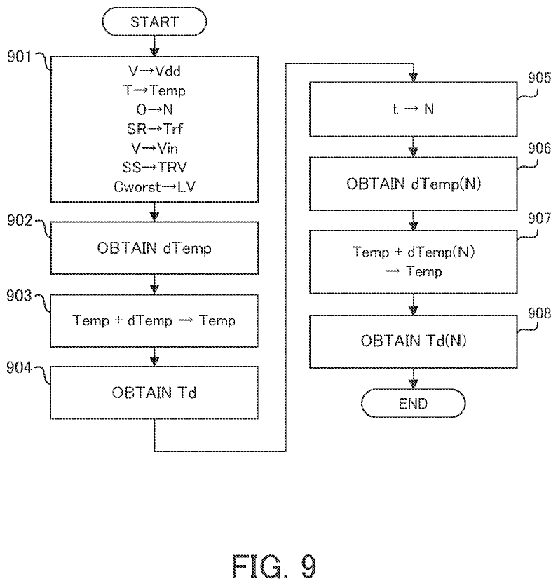

FIG. 9 is a flowchart illustrating an example of the circuit simulation in step 801 illustrated in FIG. 8. The circuit simulation illustrated in FIG. 9 is, for example, circuit simulation by SPICE.

Trf is a variable representing the slew rate of the step signal used in the circuit model, and Vin is a variable representing the maximum amplitude of the step signal. TRV is a variable representing process variation of a transistor, and LV is a variable representing process variation of a wiring resistor and a parasitic capacitance. Any condition can be selected and used as TRV and LV.

First, the generation unit 411 sets an initial condition of the circuit model (step 901). The initial condition corresponds to a state in which the performance of the integrated circuit TC is not degraded. The generation unit 411 sets a voltage V to Vdd, sets a temperature T to Temp, and sets 0 to N. Then, the generation unit 411 sets the slew rate SR to Trf, sets the voltage V to Vin, sets process variation SS to TRV, and sets process variation Cworst to LV. The values of Vin and Vdd may be different.

SS represents process variation in which a threshold voltage of an n-type metal-oxide-semiconductor field-effect transistor (MOSFET) is higher than a typical value by 3σ and a threshold voltage of a p-type MOSFET is higher than a typical value by 3σ. Cworst represents process variation that maximizes the parasitic line capacitance. The generation unit 411 may set process variation other than SS to TRV, and may set process variation other than Cworst to LV.

Next, the generation unit 411 obtains the temperature rise dTemp of the circuit model caused by a self-heating effect (SHE) by performing simulation based on a degradation model provided from a semiconductor manufacturing foundry (step 902).

Next, the generation unit 411 adds the temperature rise caused by the SHE to the temperature by setting Temp+dTemp to Temp (step 903). Then, the generation unit 411 obtains the propagation delay time Td before degradation by performing simulation using Temp (step 904). For example, in the case of the circuit model illustrated in FIG. 5, Td represents a propagation delay time between an arbitrary input and an arbitrary output in a path from the gate element LG2 to the gate element LG(M−1).

Next, the generation unit 411 sets the operating time t to N (step 905). Then, the generation unit 411 performs simulation for obtaining the average temperature rise dTemp(N) caused by the SHE when the circuit model is operated for the operating time indicated by N (step 906).

Next, the generation unit 411 adds the average temperature rise caused by the SHE to the temperature by setting Temp+dTemp(N) to Temp (step 907). Then, the generation unit 411 performs simulation based on the degradation model provided from the semiconductor manufacturing foundry to obtain the propagation delay time Td(N) after degradation when the circuit model is operated for the operating time indicated by N at the temperature indicated by Temp (step 908).

In step 908, the simulation is performed in consideration of degradation of the transistor due to bias temperature instability (BTI) and hot carrier injection (HCI).

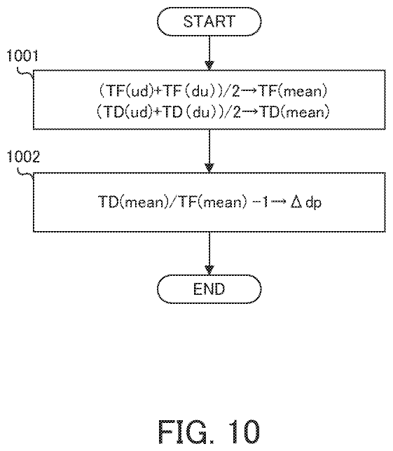

FIG. 10 is a flowchart illustrating an example of the performance degradation amount calculation processing in step 702 illustrated in FIG. 7. The generation unit 411 performs the performance degradation amount calculation processing illustrated in FIG. 10 using Td and Td(N) obtained by the circuit simulation illustrated in FIG. 9 for each combination of the voltage, the temperature, and the operating time.

TF(ud) represents Td when the step signal used in the circuit model transitions from up to down, and TF(du) represents Td when the step signal transitions from down to up. TD(ud) represents Td(N) when the step signal transitions from up to down, and TD(du) represents Td(N) when the step signal transitions from down to up.

First, the generation unit 411 sets an average value of TF(ud) and TF(du) to TF(mean), and sets an average value of TD(ud) and TD(du) to TD(mean) (step 1001). Then, the generation unit 411 subtracts 1 from the ratio of TD(mean) to TF(mean) and sets the value obtained by the subtraction to Δdp (step 1002).

In the simulation processing illustrated in FIG. 8, Vin can also be changed in addition to Vdd, the temperature, and the operating time. When K4 Vins in a predetermined voltage range are used, the number of iterations of the circuit simulation is K1×K2×K3×K4.

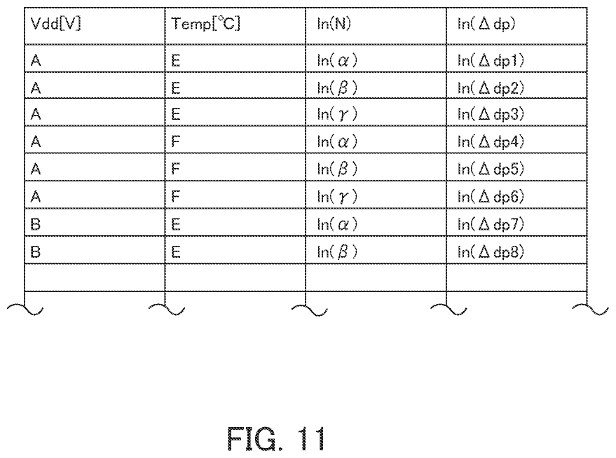

FIG. 11 illustrates an example of the performance degradation amount calculated by the performance degradation amount calculation processing illustrated in FIG. 10. ln(N) represents the natural logarithm of the operating time N, and ln(Δdp) represents the natural logarithm of the performance degradation amount Δdp calculated from a combination of the voltage Vdd, the temperature Temp, and the operating time N. ln(N) and ln(Δdp) are used in step 703 illustrated in FIG. 7.

A and B represent different voltages, E and F represent different temperatures, and α, β, and γ represent different operating times. αdp1 to αdp8 represent different performance degradation amounts, and are calculated from different combinations of Vdd, Temp, and N.

After the calculation equation for estimating Δdp is generated in step 601 illustrated in FIG. 6, the acquisition unit 412 acquires the voltage V0 and temperature TO of the integrated circuit TC from the operating integrated circuit TC and outputs the acquired voltage V0 and the acquired temperature T0 to the calculation unit 413. The calculation unit 413 sets V0 and T0 to Vdd0 and Temp0, respectively, and sets 0 to X0 and Y0 (step 602). Then, the calculation unit 413 sets Vdd0 and Temp0 to Vdd1 and Temp1, respectively, and sets 0 to N0.

Then, the calculation unit 413 stores X0 and Y0 to the storage unit 416 as operating time information 423-1 and performance degradation information 424-1, respectively. Vdd0, Temp0, X0, and Y0 represent a state in which the performance of the integrated circuit TC is not degraded.

Next, the calculation unit 413 detects a change in the operating condition at the estimation timing (step 603), and sets a correction amount NB of the operating time (step 604).

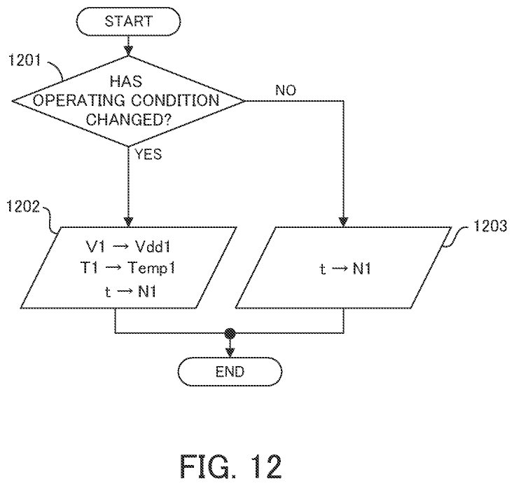

FIG. 12 is a flowchart illustrating an example of the detection processing in step 603 illustrated in FIG. 6. First, the calculation unit 413 checks whether or not the operating condition has changed (step 1201).

In step 1201, the acquisition unit 412 acquires the voltage V1 and temperature T1 of the integrated circuit TC at the estimation timing from the operating integrated circuit TC, and outputs the acquired voltage V1 and the acquired temperature T1 to the calculation unit 413.

The calculation unit 413 compares V1 and T1 with Vdd0 and Temp0, respectively, and checks whether or not the voltage or the temperature has changed. When either the voltage or the temperature has changed, it is determined that the operating condition has changed. When neither the voltage nor the temperature has changed, it is determined that the operating condition has not changed.

In a case where the operating condition has changed (YES in step 1201), the calculation unit 413 sets V1 and T1 to Vdd1 and Temp1, respectively, and sets the operating time t at the estimation timing to N1 (step 1202).

In a case where the operating condition has not changed (N0 in step 1201), the calculation unit 413 sets the operating time t at the estimation timing to N1 (step 1203).

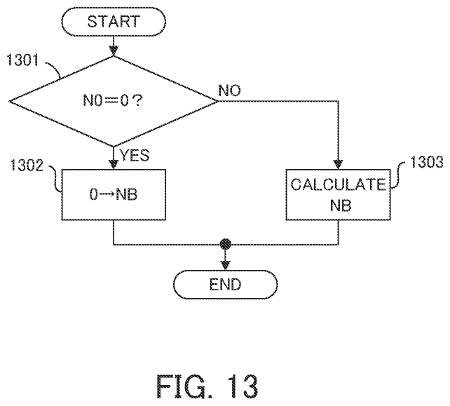

FIG. 13 is a flowchart illustrating an example of the correction amount setting processing in step 604 illustrated in FIG. 6. First, the calculation unit 413 checks whether N0=0 (step 1301).

In a case where N0 is 0 (YES in step 1301), the calculation unit 413 sets 0 to NB (step 1302). In a case where N0 is not 0 (N0 in step 1301), the calculation unit 413 calculates NB according to the following equation (step 1303).

NB=N0−exp{(Y0−a×Vdd1−b×Temp1−c)/d} (2)

When NO is not 0, it corresponds to the middle of the lapse of time. As a, b, c, and d in Equation (2), the values indicated by the calculation equation information 422 are used. N0 is an example of a first operating time, Y0 is an example of first performance degradation information corresponding to the first operating time, and Vdd1 and Temp1 are examples of a changed operating condition.

Here, a method of deriving Equation (2) will be described. When Equation (1) is transformed, the following equation is obtained.

X=ln(N)=(Y−a×Vdd−b×Temp−c)/d (3)

The following equation is obtained from Equation (3).

N=exp{(Y−a×Vdd−b×Temp−c)/d} (4)

In Equation (4), when Y=Y0, Vdd=Vdd1, and Temp=Temp1 are set, the following equation is obtained.

N=exp{(Y0−a×Vdd1−b×Temp1−c)/d} (5)

N in Equation (5) represents the operating time required for the performance degradation amount of the integrated circuit TC to reach the value corresponding to Y0 under the new voltage and temperature at the estimation timing. Therefore, the corrected N1 can be obtained by adding the difference N1−N0 between N1 and N0 to N in Equation (5). NB is calculated as a difference between N1 and the corrected N1 by the following equation.

$$\begin{matrix}N B = N 1 - exp \{ ( Y 0 - a \times Vdd 1 - b \times Temp 1 ‐ c ) / d \} - ( N 1 - N 0 ) \\ = N 0 - exp \{ ( Y 0 - a \times Vdd 1 - b \times Temp 1 ‐ c ) / d \}\end{matrix} \qquad ( 6 )$$

The right side of Equation (6) matches the right side of Equation (2). N1 is an example of a second operating time longer than the first operating time.

After the correction amount NB of the operating time is set in step 604 illustrated in FIG. 6, the calculation unit 413 corrects N1 by subtracting NB from N1 to obtain the corrected operating time N1−NB. Then, the calculation unit 413 sets ln(N1−NB) to X1 (step 605).

Next, the calculation unit 413 calculates Y1 according to the following equation (step 606).

Y1=d×X1+a×Vdd1+b×Temp1+c (7)

Then, the calculation unit 413 stores X1 and Y1 to the storage unit 416 as operating time information 423-2 and performance degradation information 424-2, respectively. Y1 is an example of second performance degradation information corresponding to the second operating time.

By calculating NB according to Equation (2) and calculating Y1 according to Equation (7) using NB, it is possible to obtain the performance degradation information in which the new voltage and temperature at the estimation timing are reflected.

The output unit 415 outputs an estimation result based on Y1. The estimation result may be Y1 or Δdp. When the estimation result is Δdp, the calculation unit 413 calculates Δdp by Δdp=exp(Y1).

Next, the calculation unit 413 compares Y1 with a threshold L (step 607). In a case where Y1 is smaller than L (YES in step 607), the calculation unit 413 sets Vdd1 and Temp1 to Vdd0 and Temp0, respectively, sets X1 and Y1 to X0 and Y0, respectively, and sets N1 to N0 (step 608). Then, the information processing apparatus 401 repeats the processing in step 603 and the subsequent steps for the next estimation timing.

In a case where Y1 is equal to or larger than L (N0 in step 607), the control unit 414 performs control in a case where the performance of the integrated circuit TC is degraded (step 609). In this case, the control unit 414 may output an error signal to the output unit 415. When the error signal is output from the control unit 414, the output unit 415 outputs warning information indicating that the performance of the integrated circuit TC has been degraded.

The information processing apparatus 401 may store Vdd0 and Vdd1 to the storage unit 416 in a first in first out (FIFO) manner. The same applies to Temp0 and Temp1, X0 and X1, and Y0 and Y1.

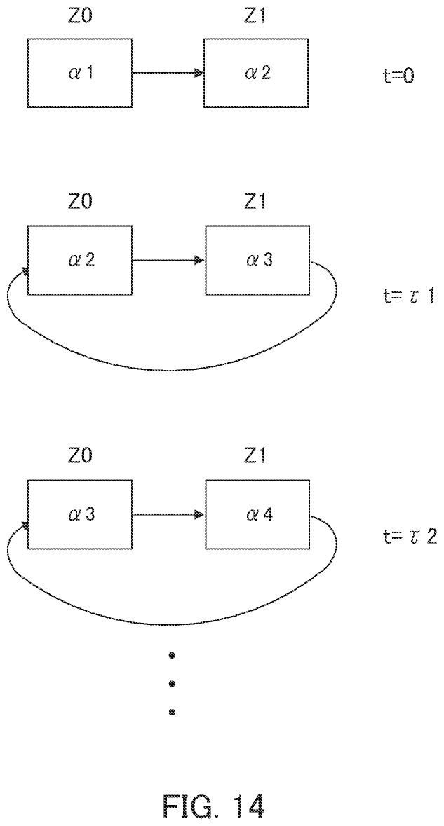

FIG. 14 illustrates an example of the variables stored in a FIFO manner. A variable Z0 represents Vdd0, Temp0, X0, or Y0, and a variable Z1 represents Vdd1, Temp1, X1, or Y1.

When the operating time t is 0, Z0 is α1 and Z1 is α2. When the operating time t is τ1, Z0 is α2 and Z1 is α3. When the operating time t is τ2, Z0 is α3 and Z1 is α4. The values of α1 to α4 are not necessarily different.

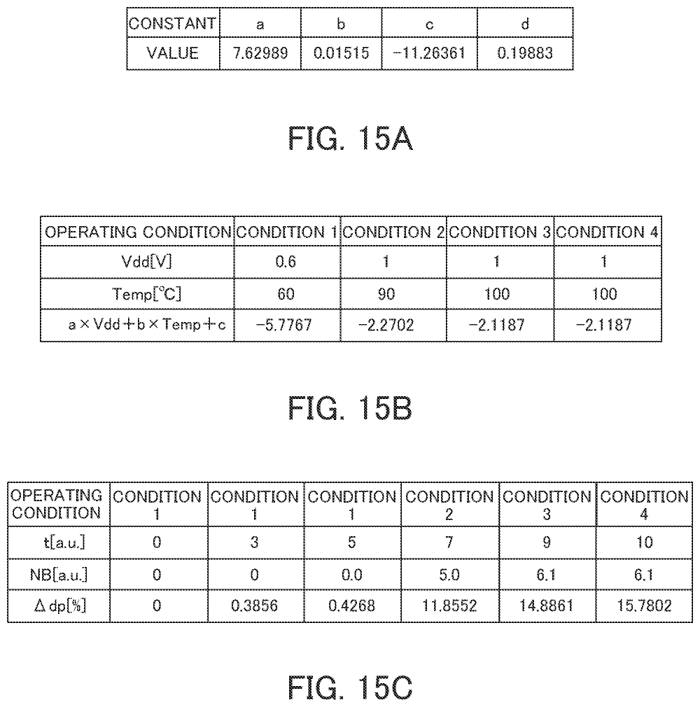

FIGS. 15A to 15C illustrate examples of the calculation results in the degradation estimation processing illustrated in FIG. 6. FIG. 15A illustrates an example of the constants indicated by the calculation equation information 422. In this example, a=7.62989, b=0.01515, c=−11.26361, and d=0.19883.

FIG. 15B illustrates examples of the operating condition. Vdd represents Vdd0 or Vdd1, and Temp represents Temp0 or Temp1. a×Vdd+b×Temp+c represents a calculation result of a×Vdd0+b×Temp0+c or a×Vdd1+b×Temp1+c. For example, in condition 1, Vdd=0.6 [V], Temp=60 [° C.], and a×Vdd+b×Temp+c=−5.7767.

FIG. 15C illustrates examples of the performance degradation amount Δdp estimated by the degradation estimation processing. The operating conditions illustrated in FIG. 15C represent operating conditions in a period from the previous estimation timing to the current estimation timing. For example, condition 2 when the operating time t is 7 [a.u.] represents an operating condition in a period from the estimation timing of t=5 to the estimation timing of t=7.

When t=0, since the performance of the integrated circuit TC is not obviously degraded, the correction amount NB of the operating time is 0 [a.u.], and Δdp is 0%.

When t=3, since N0=0, NB is set to 0. Δdp is calculated by the following equations using the operating condition illustrated in FIG. 15B, the operating time t, and NB.

Y1=d×ln(t−NB)+a×Vdd1+b×Temp1+c (8)

αdp=exp(Y1) (9)

Since the operating condition is condition 1, a×Vdd1+b×Temp1+c=−5.7767. Therefore, based on Equations (8) and (9), Δdp is about 0.39%.

When t=5, N0=3, and thus NB is calculated by Equation (2) using the operating condition illustrated in FIG. 15B. Since the operating condition is condition 1, a×Vdd1+b×Temp1+c=−5.7767. Therefore, NB is calculated by the following equations.

$$U = ( ln ( 0.003856 ) - ( - 5.7767 ) ) / 0.19883 \qquad ( 10 )$$

$$\begin{matrix}N B = 3 - exp ( U ) \\ = - 0.0021\end{matrix} \qquad ( 11 )$$

Δdp is calculated by Equations (8) and (9) using the operating condition illustrated in FIG. 15B, the operating time t, and NB. Therefore, Δdp is about 0.43%.

When t=7, N0=5 and thus NB is calculated by Equation (2) using the operating conditions illustrated in FIG. 15B. Since the operating condition is condition 2, a×Vdd1+b×Temp1+c=−2.2702. Therefore, NB is calculated by the following equations.

$$U = ( ln ( 0.004268 ) - ( - 2.2702 ) ) / 0.19883 \qquad ( 12 )$$

$$\begin{matrix}N B = 5 - exp ( U ) \\ = 5.\end{matrix} \qquad ( 13 )$$

Δdp is calculated by Equations (8) and (9) using the operating condition illustrated in FIG. 15B, the operating time t, and NB. Therefore, Δdp is about 11.9%. Similarly, NB=about 6.1 and Δdp=about 14.9 [%] when t=9, and NB=about 6.1 and Δdp=about 15.8 [%] when t=10.

Note that X in Equation (1) may be an explanatory variable representing the common logarithm log(N) of the operating time N, and Y may be an objective variable representing the common logarithm log(Δdp) of Δdp. In this case, X0 and X1 represent the common logarithm of the operating time, and Y0 and Y1 represent the common logarithm of the performance degradation amount.

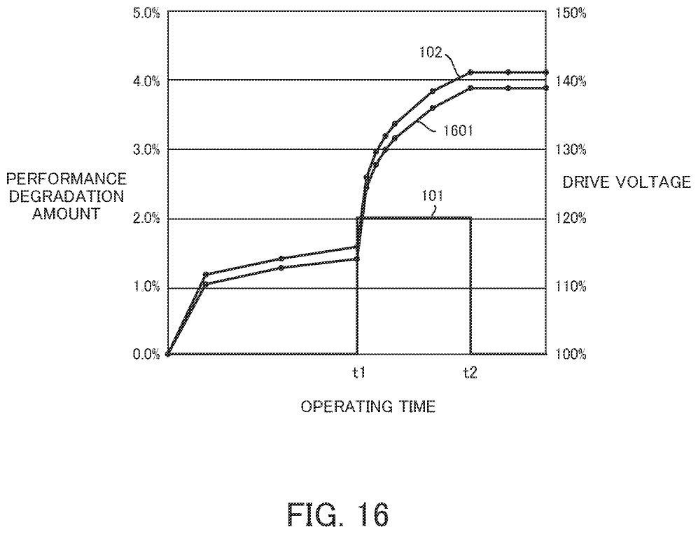

FIG. 16 is a graph illustrating an example of the performance degradation amount estimated by the second degradation estimation processing illustrated in FIG. 6. The example illustrated in FIG. 16 is different from the examples illustrated in FIGS. 15A to 15C. A temporal change in the drive voltage indicated by a polygonal line 101 illustrated in FIG. 16 and a temporal change in the actual performance degradation amount indicated by a polygonal line 102 illustrated in FIG. 16 are similar to those illustrated in FIG. 1.

A polygonal line 1601 indicates a temporal change in the performance degradation amount estimated by the degradation estimation processing illustrated in FIG. 6. Although the drive voltage increases in a time period from t1 to t2, the estimated performance degradation amount indicates a value close to the polygonal line 102 over the entire period. Therefore, it can be seen that the error is reduced as compared with the estimation result illustrated in FIG. 1.

According to the information processing apparatus 401 illustrated in FIG. 4, since it is not necessary to mount the replica circuit, and the control circuit, the measurement circuit, and the like of the replica circuit on the integrated circuit TC, the effective circuit area of the integrated circuit TC increases. In addition, by detecting a change in the operating condition in the middle of a temporal change and correcting the operating time according to the change in the operating condition, it is possible to estimate the performance degradation amount with the same accuracy as the replica circuit. Therefore, the estimation accuracy of the degradation estimation processing using the fitting equation is improved.

The operating condition of the integrated circuit TC does not necessarily include both the voltage and the temperature, and may include only one of the voltage and the temperature. By correcting the operating time according to a change in the voltage or temperature, performance degradation information in which the change is reflected can be obtained.

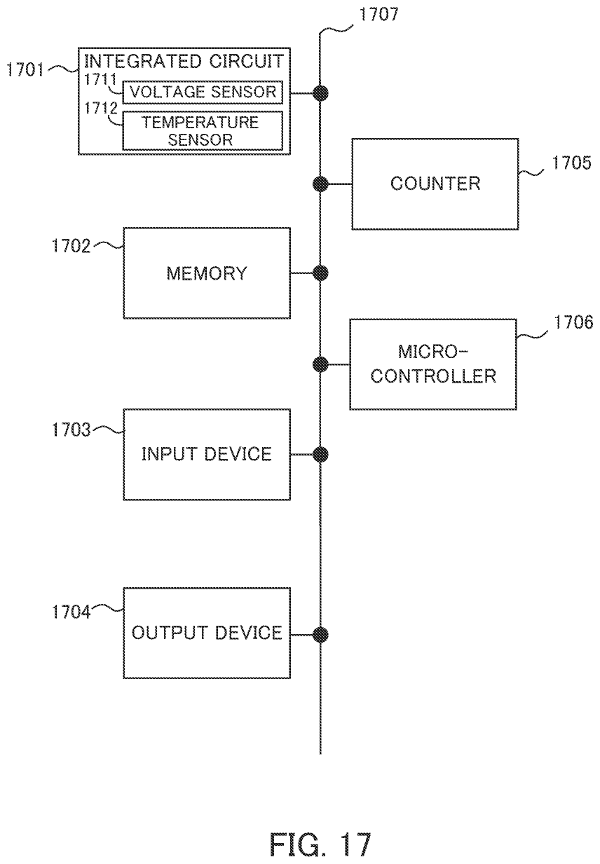

FIG. 17 illustrates a first example of a hardware configuration of the information processing apparatus 401 illustrated in FIG. 4. An information processing apparatus illustrated in FIG. 17 includes an integrated circuit 1701, a memory 1702, an input device 1703, an output device 1704, a counter 1705, and a microcontroller 1706. These components are hardware and are connected to each other by a bus 1707.

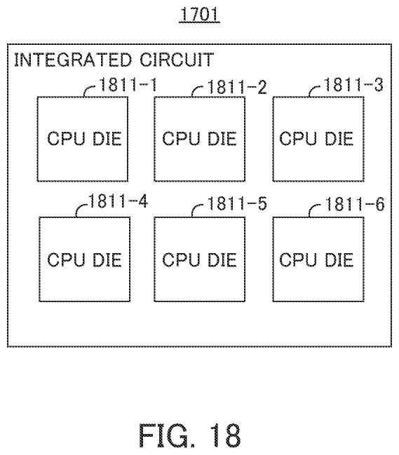

FIG. 18 illustrates an example of a hardware configuration of the integrated circuit 1701 illustrated in FIG. 17. The integrated circuit 1701 illustrated in FIG. 18 is, for example, an LSI chip, and includes CPU dies 1811-1 to 1811-6.

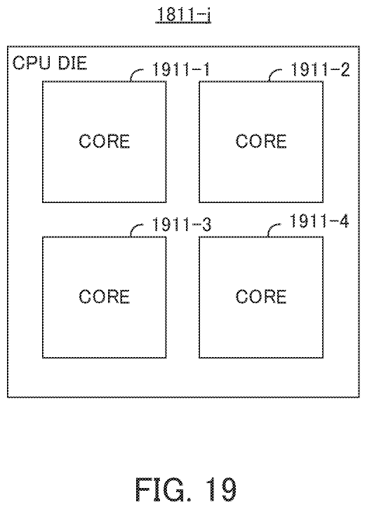

FIG. 19 illustrates an example of a hardware configuration of the CPU die 1811-j (j=1 to 6) illustrated in FIG. 18. The CPU die 1811-j illustrated in FIG. 19 includes cores 1911-1 to 1911-4 that operate at different voltages, temperatures, and frequencies. Each core 1911-k (k=1 to 4) corresponds to the integrated circuit TC.

The number of CPU dies 1811-j included in the integrated circuit 1701 may be 1 to 5 or 7 or more. The number of cores 1911-k included in each CPU die 1811-j may be 1 to 3 or 5 or more.

The integrated circuit 1701 includes a voltage sensor 1711 and a temperature sensor 1712. The voltage sensor 1711 acquires the voltage of each core 1911-k and outputs the acquired voltages to the microcontroller 1706. The temperature sensor 1712 acquires the temperature of each core 1911-k and outputs the acquired temperatures to the microcontroller 1706. The voltage sensor 1711 and the temperature sensor 1712 operate as the acquisition unit 412 illustrated in FIG. 4. The voltage sensor 1711 and the temperature sensor 1712 are hardware, and are examples of a sensor that acquires an operating condition of a target circuit.

The memory 1702 is, for example, a semiconductor memory such as a read-only memory (ROM) or a random-access memory (RAM). The memory 1702 may operate as the storage unit 416 illustrated in FIG. 4.

The counter 1705 counts the operating time based on a drive trigger signal output from the integrated circuit 1701, and outputs the counted operating time to the microcontroller 1706. The counter 1705 is reset by the microcontroller 1706. In a case where the microcontroller 1706 includes a counter, the counter 1705 may be omitted.

The microcontroller 1706 operates as the generation unit 411, the calculation unit 413, and the control unit 414 illustrated in FIG. 4, for example, by executing a firmware program. The microcontroller 1706 is an example of a control circuit that calculates performance degradation information of a target circuit. The microcontroller 1706 performs the degradation estimation processing illustrated in FIG. 6 for each core 1911-k included in each CPU die 1811-j. The microcontroller 1706 is a type of arithmetic processing device. The microcontroller 1706 may include a memory that operates as the storage unit 416 illustrated in FIG. 4.

The input device 1703 is, for example, a keyboard, a pointing device, or the like, and is used for inputting an instruction or information from an administrator. The administrator can set the operating mode of the control unit 414 using the input device 1703.

The output device 1704 is, for example, a display device, a printer, or the like, and is used for outputting an inquiry or an instruction to the administrator and outputting a processing result. The processing result may be an estimation result or warning information. The output device 1704 may operate as the output unit 415 illustrated in FIG. 4.

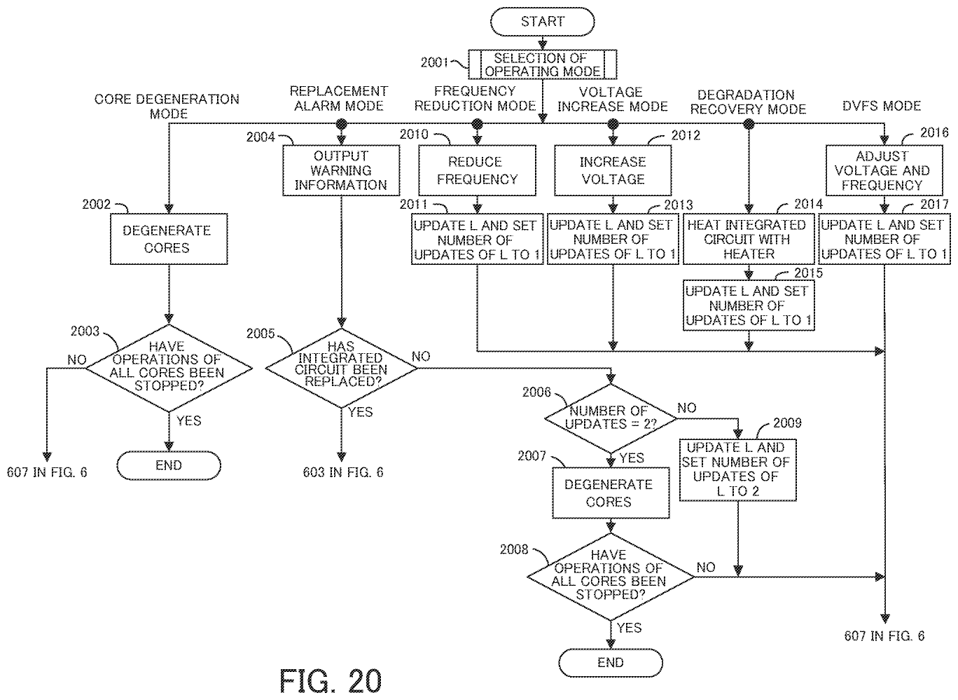

FIG. 20 is a flowchart illustrating an example of the control processing in step 609 illustrated in FIG. 6. First, the control unit 414 selects an operating mode (step 2001).

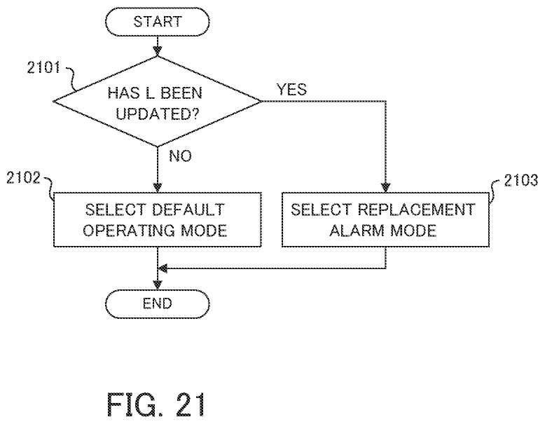

FIG. 21 is a flowchart illustrating an example of the operating mode selection processing in step 2001 illustrated in FIG. 20. First, the control unit 414 checks whether or not the threshold L for Y1 has been updated after the start of the operation of the integrated circuit TC (step 2101).

In a case where L has not been updated (NO in step 2101), the control unit 414 selects a default operating mode (step 2102). The default operating mode is preset by the administrator.

As the default operating mode, for example, a core degeneration mode, a frequency reduction mode, a voltage increase mode, a degradation recovery mode, or a DVFS mode is used. For example, in a case where reliability is emphasized, the core degeneration mode or the frequency reduction mode is used, and in a case where performance is desired to be maintained, the voltage increase mode, the degradation recovery mode, or the DVFS mode is used.

In a case where L has been updated (YES in step 2101), the control unit 414 selects a replacement alarm mode (step 2103).

After the operating mode is selected in step 2001 illustrated in FIG. 20, the control unit 414 performs control in the selected operating mode. Control for the integrated circuit 1701 having the configuration illustrated in FIGS. 17 to 19 will be described.

When the core degeneration mode is selected, the control unit 414 degenerates cores 1911-k (step 2002). In step 2002, the control unit 414 stops the supply of power to the core 1911-k having Y1 equal to or larger than L among the cores 1911-k included in each CPU die 1811-j to stop the operation of the core 1911-k having Y1 equal to or larger than L. Then, the control unit 414 continues the operations of the remaining cores 1911-k.

Next, the control unit 414 checks whether or not the operations of all the cores 1911-k have been stopped (step 2003). In a case where a core 1911-k continuing the operation is present among all the cores 1911-k (NO in step 2003), the information processing apparatus 401 repeats the processing in step 607 and the subsequent steps illustrated in FIG. 6. In a case where the operations of all the cores 1911-k have been stopped (YES in step 2003), the information processing apparatus 401 ends the processing.

According to the control in the core degeneration mode, it is possible to prevent a decrease in the reliability of the integrated circuit 1701 by stopping the operation of a core 1911-k whose performance has been degraded among all the cores 1911-k.

When the replacement alarm mode is selected, the control unit 414 outputs an error signal to the output unit 415. The output unit 415 outputs, based on the error signal, warning information indicating that the performance of the integrated circuit TC has been degraded, thereby prompting the administrator to replace the integrated circuit 1701 (step 2004). The output unit 415 may turn on a warning lamp or may display the warning information on a screen.

The administrator determines whether to replace the integrated circuit 1701 based on the warning information, and replaces the integrated circuit 1701 or resets the warning information. The control unit 414 checks whether or not the integrated circuit 1701 has been replaced (step 2005).

In a case where the integrated circuit 1701 has been replaced (YES in step 2005), the information processing apparatus 401 repeats the processing in step 603 and the subsequent steps illustrated in FIG. 6. In a case where the warning information has been reset without replacing the integrated circuit 1701 (NO in step 2005), the control unit 414 checks the number of updates of L (step 2006).

In a case where the number of updates of L is 1 (NO in step 2006), the control unit 414 further updates L and sets the number of updates of L to 2 (step 2009). Then, the information processing apparatus 401 repeats the processing in step 607 and the subsequent steps illustrated in FIG. 6.

In a case where the number of updates of L is 2 (YES in step 2006), the control unit 414 degenerates cores 1911-k (step 2007) and checks whether or not the operations of all the cores 1911-k have been stopped (step 2008).

In a case where a core 1911-k continuing the operation is present among all the cores 1911-k (NO in step 2008), the information processing apparatus 401 repeats the processing in step 607 and the subsequent steps illustrated in FIG. 6. In a case where the operations of all the cores 1911-k have been stopped (YES in step 2008), the information processing apparatus 401 ends the processing.

According to the control in the replacement alarm mode, it is possible to prevent a decrease in the reliability of the integrated circuit 1701 by replacing the integrated circuit 1701 or stopping the operation of a core 1911-k whose performance has been degraded among all the cores 1911-k.

When the frequency reduction mode is selected, the control unit 414 reduces the operating frequency of the integrated circuit 1701 to secure a margin of the propagation delay time and continues the operation (step 2010). Then, the control unit 414 updates L and sets the number of updates of L to 1 (step 2011), and the information processing apparatus 401 repeats the processing in step 607 and the subsequent steps illustrated in FIG. 6.

According to the control in the frequency reduction mode, it is possible to prevent a decrease in the reliability of the integrated circuit 1701 by securing the margin of the propagation delay time.

When the voltage increase mode is selected, the control unit 414 increases the voltage of the integrated circuit 1701 to compensate for an increase in the propagation delay time and continues the operation (step 2012). Then, the control unit 414 updates L and sets the number of updates of L to 1 (step 2013), and the information processing apparatus 401 repeats the processing in step 607 and the subsequent steps illustrated in FIG. 6.

According to the control in the voltage increase mode, the performance of the integrated circuit 1701 can be maintained by compensating for the increase in the propagation delay time.

When the degradation recovery mode is selected, the control unit 414 mainly causes the transistor to recover from the degradation of the transistor due to the BTI by heating the integrated circuit 1701 with a heater (step 2014) Then, the control unit 414 updates L and sets the number of updates of L to 1 (step 2015), and the information processing apparatus 401 repeats the processing in step 607 and the subsequent steps illustrated in FIG. 6.

According to the control in the degradation recovery mode, the performance of the integrated circuit 1701 can be maintained by causing the transistor to recover from the degradation of the transistor due to the BTI.

When the DVFS mode is selected, the control unit 414 adjusts the voltage and operating frequency of the integrated circuit 1701 so that the integrated circuit 1701 does not cause a timing error (step 2016). Then, the control unit 414 updates L and sets the number of updates of L to 1 (step 2017), and the information processing apparatus 401 repeats the processing in step 607 and the subsequent steps illustrated in FIG. 6.

According to the control in the DVFS mode, the performance of the integrated circuit 1701 can be maintained by adjusting the voltage and the operating frequency.

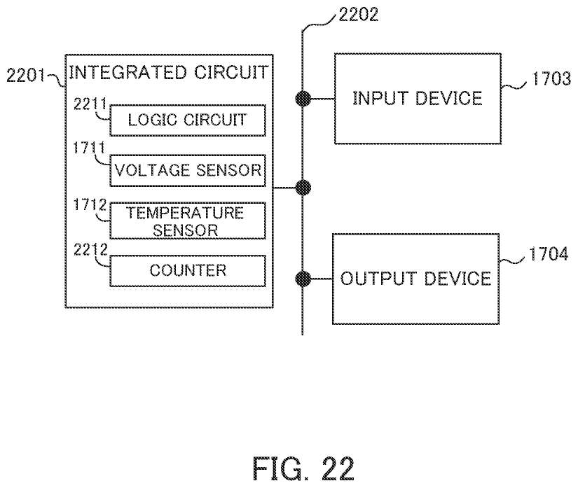

FIG. 22 illustrates a second example of the hardware configuration of the information processing apparatus 401 illustrated in FIG. 4. An information processing apparatus illustrated in FIG. 22 includes an integrated circuit 2201, an input device 1703, and an output device 1704. These components are hardware and are connected to each other by a bus 2202.

The integrated circuit 2201 includes a logic circuit 2211, a voltage sensor 1711, a temperature sensor 1712, and a counter 2212. The integrated circuit 2201 corresponds to the integrated circuit TC. The logic circuit 2211 operates as the generation unit 411, the calculation unit 413, the control unit 414, and the storage unit 416 illustrated in FIG. 4. The counter 2212 performs an operation similar to that of the counter 1705 illustrated in FIG. 17. The logic circuit 2211 is an example of the control circuit that calculates performance degradation information of a target circuit.

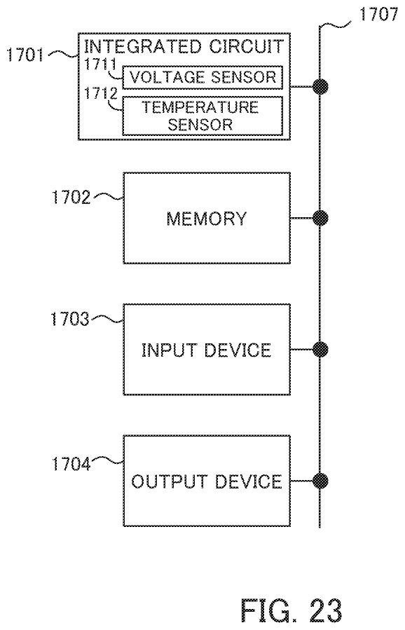

FIG. 23 illustrates a third example of the hardware configuration of the information processing apparatus 401 illustrated in FIG. 4. An information processing apparatus illustrated in FIG. 23 has a configuration obtained by removing the counter 1705 and the microcontroller 1706 from the information processing apparatus illustrated in FIG. 17.

The integrated circuit 1701 further includes an execution circuit in addition to the voltage sensor 1711 and the temperature sensor 1712. The execution circuit operates as the generation unit 411, the calculation unit 413, and the control unit 414 illustrated n FIG. 4, for example, by executing a program. The execution circuit is an example of the control circuit that calculates performance degradation information of a target circuit. The integrated circuit 1701 counts the operating time using a real-time clock (RTC) incorporated in the program. The program may be implemented as middleware. The integrated circuit 1701 performs the second degradation estimation processing illustrated FIG. 6 for each core 1911-k included in each CPU die 1811-j.

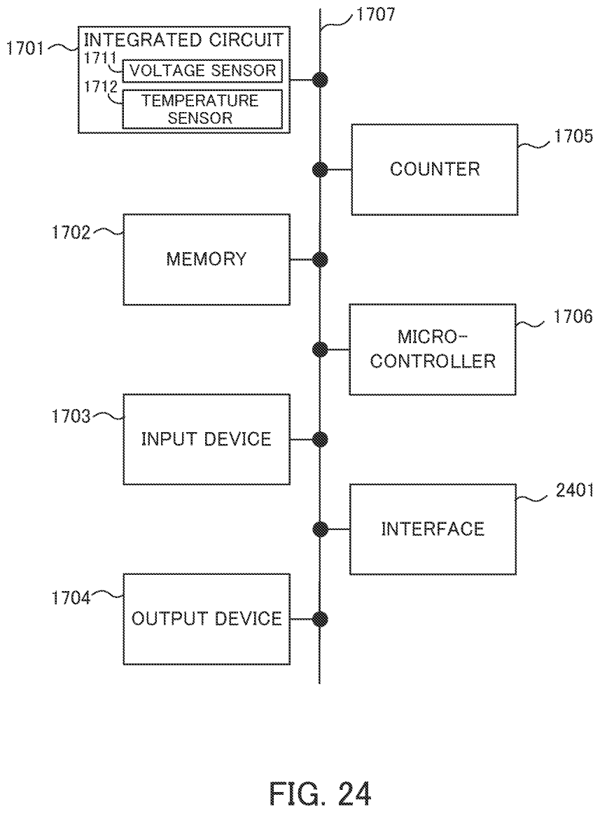

FIG. 24 illustrates a fourth example of the hardware configuration of the information processing apparatus 401 illustrated in FIG. 4. An information processing apparatus illustrated in FIG. 24 has a configuration obtained by adding an interface 2401 to the information processing apparatus illustrated in FIG. 17.

The interface 2401 is connected to a communication network such as a wide area network (WAN) or a local area network (LAN), and performs data conversion accompanying communication. The information processing apparatus can receive the values of a, b, c, and d from an external apparatus via the interface 2401, and update the calculation equation information 422 using the received values.

The configurations of the information processing apparatus 201 illustrated in FIG. 2 and the information processing apparatus 401 illustrated in FIG. 4 are merely examples, and some components may be omitted or changed according to the use or conditions of the information processing apparatuses. For example, in the information processing apparatus 401 illustrated in FIG. 4, in a case where the calculation equation information 422 is generated by an external apparatus, the generation unit 411 can be omitted. In a case where it is not necessary to perform control in a case where the performance of the integrated circuit TC is degraded, the control unit 414 can be omitted.

The configurations of the information processing apparatuses illustrated in FIGS. 17 and 22 to 24 are merely examples, and some components may be omitted or changed according to the use or conditions of the information processing apparatuses. The configurations of the integrated circuit 1701 illustrated in FIG. 18 and the CPU dies 1811-j illustrated in FIG. 19 are merely examples, and some components may be omitted or changed according to the configuration or conditions of the information processing apparatus. The integrated circuit TC may be a circuit other than the arithmetic processing device.

The flowcharts of FIGS. 3, 6 to 10, 12, 13, 20, and 21 are merely examples, and some processing may be omitted or changed according to the configurations or conditions of the information processing apparatuses. For example, in the information processing apparatus 401 illustrated in FIG. 4, in a case where the calculation equation information 422 is generated by an external apparatus, the processing in step 601 illustrated in FIG. 6 can be omitted. In a case where it is not necessary to perform control in a case where the performance of the integrated circuit TC is degraded, the processing in step 609 can be omitted.

The temporal changes in the performance degradation amounts illustrated in FIGS. 1 and 16 are merely examples, and the performance degradation amount varies depending on the integrated circuit TC and the operating condition. The circuit model illustrated in FIG. 5 is merely an example, and a fitting equation may be generated using another circuit model. The combinations of the voltage, the temperature, and the operating time illustrated in FIG. 11 are merely examples, and circuit simulation may be performed using another combination.

The variable storage method illustrated in FIG. 14 is merely an example, and each variable may be stored in another format. The calculation results illustrated in FIGS. 15A to 15C are merely examples, and the calculation results vary depending on the integrated circuit TC and the operating condition.

Equations (1) to (13) are merely examples, and the information processing apparatus 401 may perform the degradation estimation processing using another calculation equation.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. An information processing apparatus comprising:
a sensor that acquires an operating condition of a target circuit; and
a control circuit that, when the operating condition changes, corrects an operating time of the target circuit based on a changed operating condition to obtain a corrected operating time, and calculates performance degradation information of the target circuit by using the changed operating condition and the corrected operating time.

2. The information processing apparatus according to claim 1, wherein
the control circuit obtains a correction amount of an operating time based on a first operating time, first performance degradation information corresponding to the first operating time, and the changed operating condition, obtains the corrected operating time based on a second operating time longer than the first operating time and the correction amount of the operating time, calculates second performance degradation information corresponding to the second operating time by using the changed operating condition and the corrected operating time, and uses the second performance degradation information as the performance degradation information of the target circuit.

3. The information processing apparatus according to claim 1, wherein
the control circuit performs, based on a result of comparing the performance degradation information of the target circuit with a threshold, control in a case where performance of the target circuit is degraded.

4. The information processing apparatus according to claim 1, wherein
the operating condition includes at least one of a voltage of the target circuit or a temperature of the target circuit.

5. A degradation estimation method comprising:
acquiring an operating condition of a target circuit;
when the operating condition changes, correcting, by an information processing apparatus, an operating time of the target circuit based on a changed operating condition to obtain a corrected operating time; and
calculating, by the information processing apparatus, performance degradation information of the target circuit by using the changed operating condition and the corrected operating time.

6. The degradation estimation method according to claim 5, wherein
the obtaining the corrected operating time includes:
obtaining a correction amount of an operating time based on a first operating time, first performance degradation information corresponding to the first operating time, and the changed operating condition; and
obtaining the corrected operating time based on a second operating time longer than the first operating time and the correction amount of the operating time, and
the calculating the performance degradation information of the target circuit includes:
calculating second performance degradation information corresponding to the second operating time by using the changed operating condition and the corrected operating time; and
using the second performance degradation information as the performance degradation information of the target circuit.

7. The degradation estimation method according to claim 5, further comprising
performing, based on a result of comparing the performance degradation information of the target circuit with a threshold, control in a case where performance of the target circuit is degraded.

8. The degradation estimation method according to claim 5, wherein
the operating condition includes at least one of a voltage of the target circuit or a temperature of the target circuit.
